(19) United States
(12) Patent Application Publication
(10) Pub. No.: US 2004/0092108 A1
(43) Pub. Date: May 13, 2004

(54) Method of processing a semiconductor wafer

(76) Inventors: Kouichi Yajima, Tokyo (JP); Masahiko Kitamura, Tokyo (JP); Shinichi Namioka, Tokyo (JP); Masatoshi Nanjo, Tokyo (JP)

Correspondence Address: SMITH, GAMBRELL & RUSSELL, LLP, 1850 M STREET, N.W., SUITE 800, WASHINGTON, DC, 20036, US

(21) Appl. No.: 10/694,179

(22) Filed: Oct. 28, 2003

(30) Foreign Application Priority Data
Nov. 1, 2002 (JP) 2002-319279

(51) Int. Cl. H01L 21/302; H01L 21/461

(52) U.S. Cl. 438/689

(57) ABSTRACT

A method of processing a semiconductor wafer having a large number of rectangular areas sectioned by streets arranged in a lattice form on the front surface, circuits being formed in the respective areas. This method comprises the step of mounting a semiconductor wafer on a protective substrate in such a manner that the front surface of the semiconductor wafer is opposed to one side of the protective substrate having a large number of pores in at least its central area prior to the grinding of the back surface of the semiconductor wafer.

### FIELD OF THE INVENTION

The present invention relates to a method of processing a semiconductor wafer, which has a large number of rectangular areas sectioned by streets arranged in a lattice form on the front surface, circuits being formed in the respective rectangular areas. More specifically, it relates to a method of processing a semiconductor wafer, comprising the step of grinding the back surface of the semiconductor wafer by a grinding means and the step of cutting the semiconductor wafer along the streets by applying a cutting means to the front surface of the semiconductor wafer.

### DESCRIPTION OF THE PRIOR ART

As well known among people of ordinary skill in the art, in the production of semiconductor chips, a large number of rectangular areas are sectioned by streets arranged in a lattice form on the front surface of a semiconductor wafer, and a semiconductor circuit is formed in each of the rectangular areas. The back surface of the semiconductor wafer is ground to reduce the thickness of the semiconductor wafer and then, the semiconductor wafer is cut along the streets to separate the rectangular areas from one another so as to form semiconductor chips. To grind the back surface of the semiconductor wafer, a protective resin tape is affixed to the front surface of the semiconductor wafer to protect the semiconductor circuits, the semiconductor wafer is held on a chuck means for grinding in a state of the front surface having the tape affixed thereto facing down, that is, the front surface and the back surface of the semiconductor being inverted, and the grinding means is applied to the back surface of the semiconductor wafer. To cut the semiconductor water along the streets, the semiconductor wafer is mounted on a holding means. The holding means is generally constituted by a mounting frame having a mounting opening at the center and an adhesive tape affixed to the mounting frame in such a manner that it strides over the mounting opening, and the back surface of the semiconductor wafer is affixed to the mounting tape in the mounting opening of the mounting frame in order to mount the semiconductor wafer on a mounting means. The protective resin tape affixed to the front surface of the semiconductor wafer is removed off, the mounting means mounting the semiconductor wafer is held on a chuck means for cutting, and a cutting means is applied to the exposed front surface of the semiconductor wafer.

Nowadays, it is often desired that the thickness of the semiconductor wafer should be greatly reduced, for example, to 100 μm or less, particularly 50 μm or less, in order to form a very small-sized and lightweight semiconductor chip. Accordingly, when the thickness of the semiconductor wafer becomes very small, the stiffness of the semiconductor wafer becomes very low, thereby making it extremely difficult to handle the semiconductor wafer, for example, to convey the semiconductor wafer to mount it on the holding means after it is removed off from the chuck means for grinding. When a tape having relatively high stiffness, such as a polyethylene terephthalate film or sheet having a relatively large thickness is used as the protective resin tape affixed to the front surface of the semiconductor wafer by a suitable adhesive, the semiconductor wafer becomes able to be conveyed. However, when a tape having relatively high stiffness is affixed to the front surface of the semiconductor wafer, it is extremely difficult to strip off the tape from the front surface of the semiconductor wafer without causing damage to the semiconductor wafer.

### SUMMARY OF THE INVENTION

It is the principal object of the present invention to provide a novel and excellent method of processing a semiconductor wafer, which enables the semiconductor wafer to be handled as desired without damaging it even when the back surface of the semiconductor wafer is ground to extremely reduce its thickness.

In the present invention, to attain the above principal object, prior to the grinding of the back surface of the semiconductor wafer, the semiconductor wafer is mounted on a protective substrate in such a manner that the front surface of the semiconductor wafer is opposed to one side of the protective substrate having a great number of pores in at least its central area.

That is, according to the present invention, to attain the above principal object, there is provided a method of processing a semiconductor wafer having a large number of rectangular areas sectioned by streets arranged in a lattice form on the front surface, circuits being formed in the respective areas, comprising:

the mounting step of mounting the semiconductor wafer on a protective substrate in such a manner that the front surface of the semiconductor wafer is opposed to one side of a protective substrate having a great number of pores in at least its central area;

the grinding step of holding the protective substrate mounting the semiconductor wafer on a chuck means for grinding and grinding the exposed back surface of the semiconductor wafer with a grinding means;

the transfer step of removing the protective substrate off from the chuck means for grinding, then affixing the back surface of the semiconductor wafer mounted on the protective substrate removed off from the chuck means for grinding on a holding means and thereafter, removing the protective substrate off from the front surface of the semiconductor wafer; and

the cutting step of holding the holding means mounting the semiconductor wafer on a chuck means for cutting and applying a cutting means to the exposed front surface of the semiconductor wafer to cut the semiconductor wafer along the streets.

In a preferred embodiment, the holding means is constituted by a mounting frame having a mounting opening at the center and a mounting tape affixed to the mounting frame in such a manner that it strides over the mounting opening, and in the transfer step, the back surface of the semiconductor wafer mounted on the protective substrate removed off from the chuck means for grinding is affixed to the mounting tape in the mounting opening of the mounting frame in order to mount the semiconductor wafer on the holding means. Preferably, in the mounting step, a resin solution is coated onto the front surface of the semiconductor wafer, a solvent is evaporated before or after the front surface of the semiconductor wafer is caused to be opposed to one side of the protective substrate in order to form a resin film having adhesion, and the semiconductor wafer is mounted on the protective substrate via the resin film. Preferably, the resin solution is applied to the front surface of the semiconductor wafer by supplying resin solution droplets onto the front surface of the semiconductor wafer and rotating the semiconductor wafer at a revolution of 10 to 3,000 rpm. Preferably, the resin film has a thickness of 1 to 100 μm. Preferably, in the transfer step, prior to the removal of the protective substrate from the front surface of the semiconductor wafer, a solvent is supplied to the resin film through the pores of the protective substrate to dissolve the resin film. Preferably, the resin solution is water-soluble, and the solvent is water.

In the mounting step, the front surface of the semiconductor wafer can be adhered to the one side of the protective substrate by an adhesive double-coated tape. Alternatively, in the mounting step, the front surface of the semiconductor wafer and the one side of the protective substrate can be contact bonded together via water. Prior to contact bonding the front surface of the semiconductor wafer to the one side of the protective substrate via water, a protective resin tape is preferably affixed to the front surface of the semiconductor wafer. In the transfer step, the protective substrate is heated to evaporate water existing between the front surface of the semiconductor wafer and the protective substrate.

Preferably, in the transfer step, prior to the affixing of the back surface of the semiconductor wafer to the mounting means, a die attach film is affixed to the back surface of the semiconductor wafer. Preferably, the protective substrate has a frame area surrounding the central area, pores are not formed in the frame area, and the semiconductor wafer is mounted within the central area of the protective substrate. Preferably, the area ratio of the pores to the central area of the protective substrate is 1 to 50%, and the pores have a diameter of 0.1 to 1.0 mm. Preferably, the protective substrate is formed of a sheet metal having a thickness of 0.1 to 1.0 mm.

### BRIEF DESCRIPTION OF THE DRAWINGS

FIG. 1 is a perspective view of a typical example of a semiconductor wafer;

FIG. 2 is a perspective view showing a mounting step for mounting a semiconductor wafer on a protective substrate via a resin film;

FIG. 3 is a sectional view showing a state of grinding of the back surface of the semiconductor wafer mounted on the protective substrate via the resin film;

FIG. 4 is a perspective view showing a manner that a die attach film is affixed to the back surface of the semiconductor wafer in the transfer step;

FIG. 5 is a perspective view showing a manner that the semiconductor wafer is mounted on holding means in the transfer step;

FIG. 6 is a perspective view showing a state of the semiconductor wafer mounted on the holding means;

FIG. 7 is a perspective view showing a state of the protective substrate having been removed off from the semiconductor wafer mounted on the holding means; and

FIG. 8 is a sectional view showing a state of the semiconductor wafer being cut along a street.

### DETAILED DESCRIPTION OF THE PREFERRED EMBODIMENTS

The method of processing a semiconductor wafer according to a preferred embodiment of the present invention will be described in detail hereinunder with reference to the accompanying drawings.

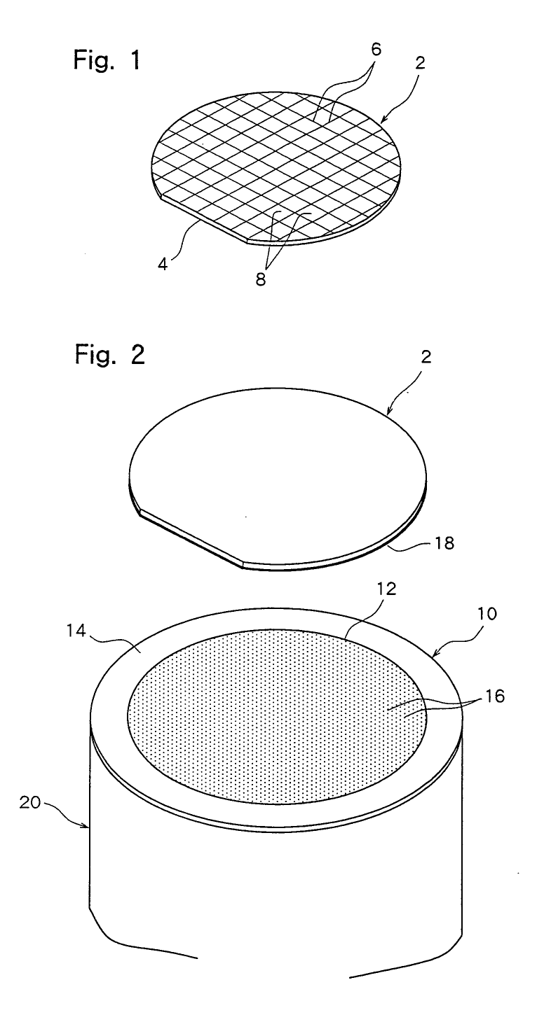

FIG. 1 shows a typical example of a semiconductor wafer. The illustrated semiconductor wafer 2 is shaped like a disk and has a linear edge 4 called “orientation flat” formed at part of the periphery of the disk and a large number of rectangular areas 8 sectioned by streets 6 arranged in a lattice form on the front surface. A semiconductor circuit is formed in each of the rectangular areas 8.

With reference to FIG. 1 and FIG. 2, in the method of processing a semiconductor wafer according to the present invention, the step of mounting the semiconductor wafer 2 on a protective substrate 10 is first carried out. The illustrated protective substrate 10 is shaped like a disk as a whole and has a circular central area 12 and an annular frame area 14. The central area 12 has a diameter that corresponds to that of the semiconductor wafer 2. A large number of pores 16 are formed in the central area 12. The area ratio of the pores 16 to the central area 12 is 1 to 50%, and the pores have a diameter of preferably 0.1 to 1.0 mm, particularly preferably about 0.5 mm. Pores are not formed in the frame area 14 which is solid. The protective substrate 10 is advantageously formed of a sheet metal having a thickness of 0.1 to 1.0 mm, particularly about 0.5 mm, such as a SUS420 stainless steel sheet having spring characteristics. The protective substrate 10 may be formed of a suitable synthetic resin, as desired.

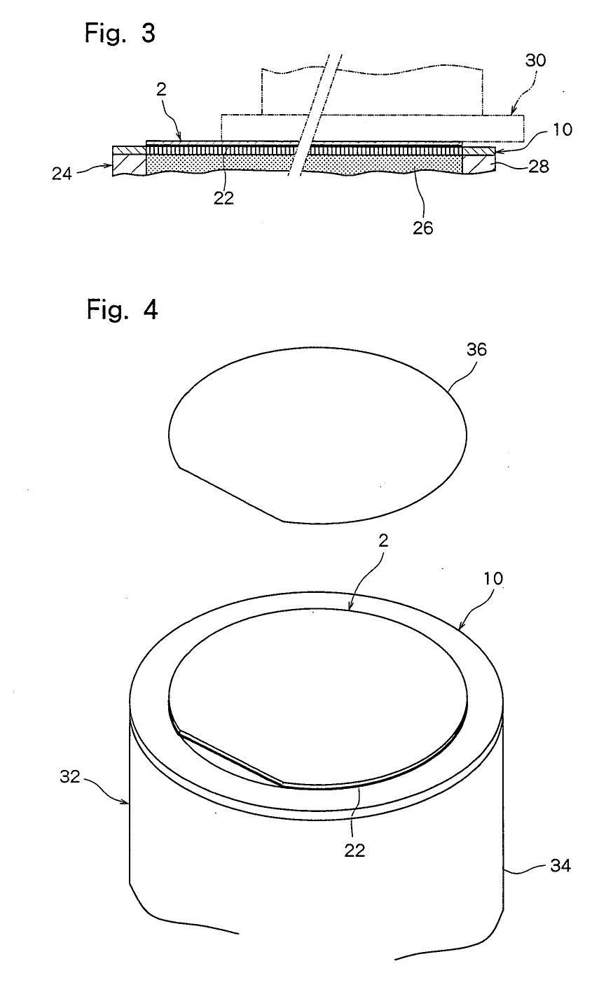

In the preferred embodiment of the present invention, to mount the semiconductor wafer 2 on the protective substrate 10, a resin solution 18 is coated on the front surface of the semiconductor wafer 2. The coating of the resin solution 18 can be advantageously carried out by supplying resin solution droplets onto the front surface of the semiconductor wafer 2 and rotating the semiconductor wafer 2 at a revolution of about 10 to 3,000 rpm. Then, this semiconductor wafer 2 is superposed on the central area 12 of the protective substrate 10 in such a manner that one side (top face in FIG. 2) of the protective substrate 10 placed on support means 20 is opposed to the front surface coated with the resin solution 18 of the semiconductor wafer 2. The support means 20 has a suitable heating means (not shown) such as an electric resistance heater, which is built-in. After the semiconductor wafer 2 is interposed on the central area 12 of the protective substrate 10, the heating means built-in in the support means 20 is operated to heat the resin solution 18 at 80 to 250° C. so as to evaporate the solvent contained in the resin solution 18, thereby forming a resin film 22 (see FIG. 3). Thus, the semiconductor wafer 2 is mounted on the central area 12 of the protective substrate 10 with the resin film 22 therebetween. The formed resin film 22 has a thickness of around 1 to 100 μm. The resin solution 18 is preferably a water-soluble resin solution for forming the resin film 22 having suitable adhesion, such as a water-soluble resin solution marketed by Tokyo Ohka Kogyo Co., Ltd. under the trade name of TPF.

In the above embodiment, after the semiconductor wafer 2 is mounted on the protective substrate 10, the resin solution 18 is heated to form the resin film 22. After the resin solution 18 is heated to form the resin film 22, the semiconductor wafer 2 may be mounted on the protective substrate 10. As desired, the resin solution 18 applied to the front surface of the semiconductor wafer 2 is heated to form the resin film 22 once, the semiconductor wafer 2 is kept, the solvent is supplied to the resin film 22 to make it into the resin solution 18 at the time when the semiconductor wafer 2 is mounted on the protective substrate 10, and then, the resin solution 18 is heated to form the resin film 22 again after superposing the semiconductor wafer 2 onto the protective substrate 10.

Further, in the above embodiment, the semiconductor wafer 2 is mounted on the protective substrate 10 via the resin film 22 therebetween. Alternatively, the semiconductor wafer 2 may be mounted on the central area 12 of the protective substrate 10 by a suitable adhesive double-coated tape. Preferably, the adhesive applied to at least one side of the adhesive double-coated tape, which is brought into close contact with the front surface of the semiconductor wafer 2 is curable through exposure to ultraviolet radiation, by heating or through exposure to laser radiation. According to the experience of the inventors of the present invention, it has been found that when water is interposed between the central area 12 of the protective substrate 10 and the front surface of the semiconductor wafer 2 to contact bond them together, the semiconductor wafer 2 can be mounted on the central area 12 of the protective substrate 10 by suitable adhesion. In this case, to protect the circuits formed on the front surface of the semiconductor wafer 2, it is desired that a suitable protective tape be affixed to the front surface of the semiconductor wafer 2 before the front surface of the semiconductor wafer 2 is contact bonded to the central area 12 of the protective substrate 10. As the preferable. protective tape, there is enumerated a polyolefin film which has relatively low stiffness and is coated with an ultraviolet curable, thermally curable or laser curable adhesive on one side to be brought into close contact with the front surface of the semiconductor wafer 2.

Continuing the description with reference to FIG. 3, the grinding step is carried out subsequent to the above mounting step. In this grinding step, the protective substrate 10 mounting the semiconductor wafer 2 is held on a chuck means 24 for grinding, and the back surface of the semiconductor wafer 2 is exposed. The chuck means 24 for grinding has a disk-like porous central member 26 and an annular casing 28 surrounding the central member 26. The diameter of the central member 26 fixed in the annular casing 28 is made the same as that of the central area 12 of the protective substrate 10. As desired, the diameter of the central member 26 may be made the same as that of the entire protective substrate 10. The top face of the central member 26 and the top face of the annular casing 28 are flush with each other. At the time when the back surface of the semiconductor wafer 2 is ground, the central area 12 of the protective substrate 10 mounting the semiconductor wafer 2 is aligned with the central member 26 of the chuck means 24 for grinding and then, the semiconductor wafer 2 is placed on the chuck means 24 for grinding. Thereafter, the central member 26 is connected to a vacuum source (not shown) to suck the air through the central area 12 of the protective substrate 10 and the central member 26 of the chuck means 24 for grinding in order to adsorb the semiconductor wafer 2 to the chuck means 24 for grinding via the protective substrate 10. Then, the exposed back surface of the semiconductor wafer 2 is ground with a grinding means 30. The grinding means 30 is constituted by an annular grinding tool, and grinding pieces containing diamond particles are provided on the undersurface of the grinding tool. The chuck means 24 for grinding which adsorbs the semiconductor wafer 2 is rotated on its center axis, and the grinding means 30 is also rotated on its center axis, and pressed against the back surface of the semiconductor wafer 2 to grind the back surface of the semiconductor wafer 2. This grinding step can be advantageously carried out with a suitable grinder, for example, a grinder marketed by DISCO CORPORATION under the trade name of DFG841.

After the back surface of the semiconductor wafer 2 is ground as desired in the above grinding step, the transfer step is carried out. In this transfer step, the chuck means 24 for grinding is shut off from the vacuum source to cancel the suction function of the chuck means 24 for grinding, thereby removing off the protective substrate 10 and the semiconductor wafer 2 mounted on this protective substrate 10 from the chuck means 24 for grinding. The removal of the semiconductor wafer 2 off from the chuck means 24 for grinding and the conveyance of the removed semiconductor wafer 2 can be carried out by holding the protective substrate 10. Therefore, even when the thickness of the semiconductor wafer 2 is greatly reduced, the semiconductor wafer 2 can be removed off and carried without damaging it. In the illustrated embodiment, as shown in FIG. 4, the removed protective substrate 10 and semiconductor wafer 2 are placed on a support means 32. The support means 32 has a disk-like central member (not shown) and an annular casing 34 surrounding this central member. The diameter of the central member fixed in the annular casing 34 corresponds to that of the central area 12 of the protective substrate 10. The top face of the central member and the top face of the annular casing 34 are flush with each other. A heating means (not shown) such as an electric resistance heater is built in the annular casing 34. Continuing the description with reference to FIG. 4, to place the protective substrate 10 and the semiconductor wafer 2 on the support means 32, the heating means is operated to heat the central member at 80 to 200° C. Then, the central member is connected to the vacuum source (not shown) to suck the air through the central area 12 of the protective substrate 10 and the central member of the support means 32 so as to adsorb the semiconductor wafer 2 onto the support means 32 via the protective substrate 10. Then, one side of a die attach film 36 that is known per se is brought into close contact with the exposed back surface of the semiconductor wafer 2 so as to affix the die attach film 36 to the back surface of the semiconductor wafer 2. The die attach film 36 may have substantially the same shape as the semiconductor wafer 2. Thereafter, the operation of the heating means is stopped to cool the semiconductor wafer 2 and the die attach film 36 to normal temperature.

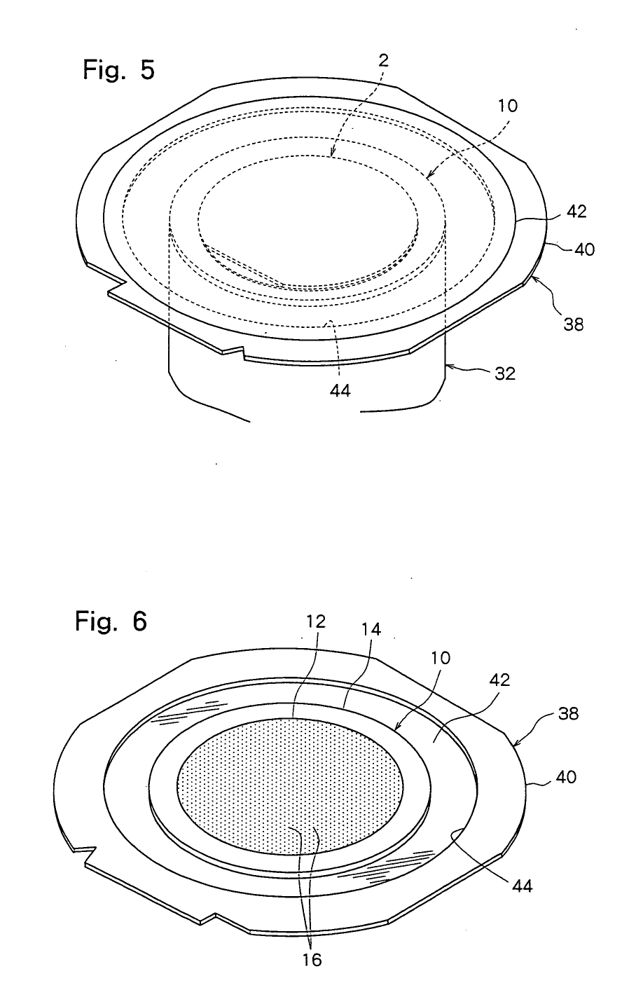

Thereafter, in the illustrated embodiment, as shown in FIG. 5, a holding means 38 is mounted on the back surface of the semiconductor wafer 2 held on the support means 32. The illustrated holding means 38 is constituted by a mounting frame 40 and a mounting tape 42. The mounting frame 40 which can be formed of a suitable sheet metal or synthetic resin has a relatively large mounting opening 44 at the center. The mounting tape 42 is affixed to one side (top surface in FIG. 5) of the mounting frame 40 in such a way that it strides over the mounting opening 44. One side (under surface in FIG. 5) of the mounting tape 42 is adhesive. The back surface of the semiconductor wafer 2 is positioned in the mounting opening 44 of the mounting frame 40, and the mounting tape 42 is affixed to the back surface of the semiconductor wafer 2. Thus, the mounting frame 40 is connected to the back surface of the semiconductor wafer 2 via the mounting tape 42, and the semiconductor wafer 2 and the protective substrate 10 are mounted on the holding means 38. FIG. 6 shows a state in which the mounting frame 40, mounting tape 42, semiconductor wafer 2 and protective substrate 10, which are integrally combined, are removed off from the support means 32 and inverted, that is, the mounting tape 42 is located at the lowest position and the protective substrate 10 is located at the highest position. As desired, other types of the mounting means such as a holding means composed of a disk-like sheet may be used in place of the holding means 38 composed of the mounting frame 40 and the mounting tape 42.

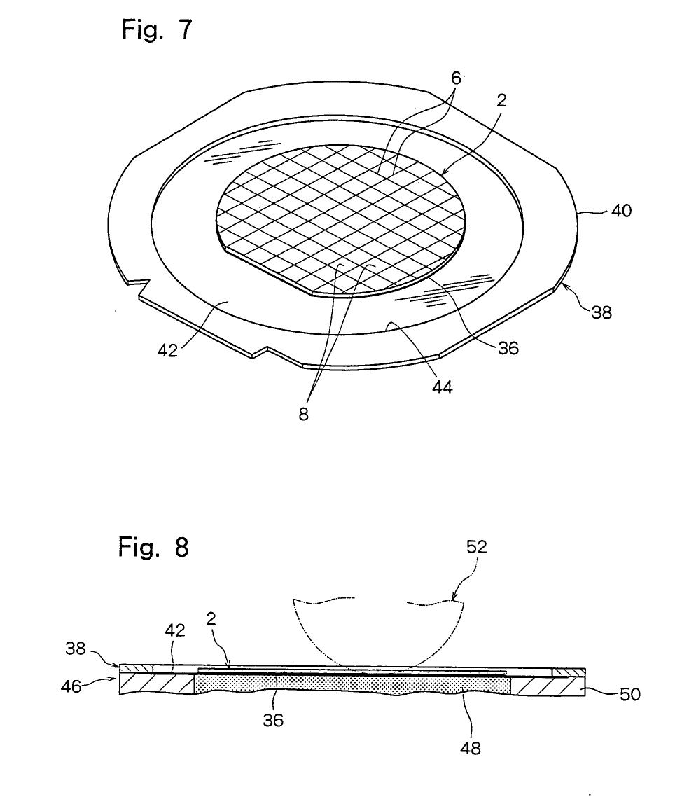

The protective substrate 10 is then removed off from the front surface of the semiconductor wafer 2. Thereby, as shown in FIG. 7, there can be obtained the state where the semiconductor wafer 2 with the front surface being exposed upward is mounted on the mounting frame 40 via the mounting tape 42. When the front surface of the semiconductor wafer 2 and the protective substrate 10 are joined together by the resin film 22, a solvent is supplied to the resin film 22 through pores 16 formed in the central area 12 of the protective substrate 10 to change the resin film 22 into a resin solution 18 so that the protective substrate 10 can be easily removed off from the front surface of the semiconductor wafer 2 without damaging the semiconductor wafer 2. In this case, when the resin film 22 is formed of a water-soluble resin solution 18, water is used in place of water. It should be also noted that the pores 16 being formed in the central area 12 of the protective substrate 10 suitably reduces bonding force between the front surface of the semiconductor wafer 2 and the protective substrate 10. When the semiconductor wafer 2 and the protective substrate 10 are assembled together by the adhesive double-coated tape and the adhesive brought into close contact with the semiconductor wafer 2 is, for example, an ultraviolet curable adhesive, the adhesive is exposed to ultraviolet light to reduce its adhesion, thereby making it possible to promote the removal of the protective substrate 10 off from the front surface of the semiconductor wafer 2. When the resin film 22 is, for example, curable with ultraviolet light, the removal of the protective substrate 10 can be promoted. When the adhesive brought into close contact with the semiconductor wafer 2 is curable with ultraviolet light, prior to the grinding of the back surface of the semiconductor wafer 2, the adhesive is exposed to ultraviolet light to be cured, so that its elastic modulus is also increased. Although bonding force between the front surface of the semiconductor wafer 2 and the protective substrate 10 is reduced thereby, the grinding accuracy of the back surface of the semiconductor wafer 2 is improved due to the increased elastic modulus of the adhesive (as for this, refer to JP-A 10-50642). When the front surface of the semiconductor wafer 2 and the protective substrate 10 are contact bonded together under existence of water to be assembled together, the protective substrate 10 and the semiconductor wafer 2 are suitably heated to evaporate water existing therebetween, thereby making it possible to promote the removal of the protective substrate 10 off from the front surface of the semiconductor wafer 2.

The cutting step is carried out after the above transfer step. Describing this step with reference to FIG. 7 and FIG. 8, in the cutting step, the holding means 38 mounting the semiconductor wafer 2 is mounted on a chuck means 46 for cutting while the front surface of the semiconductor wafer 2 is exposed. The chuck means 46 for cutting has a disk-like porous central member 48 and an annular casing 50 surrounding this central member 48. The outer diameter of the central member 48 is made substantially the same as that of the semiconductor wafer 2. The top face of the central member 48 and the top face of the annular casing 50 are flush with each other. To cut the semiconductor wafer 2, the semiconductor wafer 2 mounted on the holding means 38 is positioned onto the chuck means 46 for cutting via the mounting tape 42, and vacuum-adsorbed to the central member 48 through the mounting tape 42 by sucking the air through the central member 48. The mounting frame 40 is fixed to the annular casing 50 by a clamp means (not shown) provided in the annular casing 50. A cutting means 52 is applied to the front surface, exposed upward, of the semiconductor wafer 2 to cut it along the streets 6. The cutting means 52 is constituted by a disk-like cutting blade, and is rotated at a high speed to act its peripheral edge on the semiconductor wafer 2. The chuck means 46 for cutting is then moved relative to the cutting means 52 along the streets 6 (FIG. 1 and FIG. 7). The semiconductor wafer 2 is thus divided into the individual rectangular areas 8 (FIG. 1 and FIG. 7). Whereas the die attach film 36 is cut, the mounting tape 42 is kept uncut, whereby the individually separated rectangular areas 8 are kept mounted on the mounting frame 40 by the mounting tape 42. The cutting of the semiconductor wafer 2 can be advantageously carried out with a suitable cutting machine, for example, a cutting machine marketed by DISCO CORPORATION under the trade name of DFD6000 series. As desired, a cutting machine making use of a laser beam may be used as the cutting means. After the semiconductor wafer 2 is divided into the individual rectangular areas 8, the rectangular areas 8 kept mounted on the mounting frame 40 are removed off from the chuck means 46 for cutting by holding the mounting frame 40 and taken out from the mounting frame 40 to obtain semiconductor chips.

While a preferred embodiment of the present invention has been described with reference to the accompanying drawings, it should be understood that the present invention is not limited to this embodiment and that various changes and modifications may be made in the invention without departing from the spirit and scope thereof.

What is claimed is:

1. A method of processing a semiconductor wafer having a large number of rectangular areas sectioned by streets arranged in a lattice form on the front surface, circuits being formed in the respective areas, comprising:
the mounting step of mounting the semiconductor wafer on a protective substrate in such a manner that the front surface of the semiconductor wafer is opposed to one side of a protective substrate having a large number of pores in at least its central area;
the grinding step of holding the protective substrate mounting the semiconductor wafer on a chuck means for grinding and grinding the exposed back surface of the semiconductor wafer with a grinding means;
the transfer step of removing the protective substrate off from the chuck means for grinding, then affixing the back surface of the semiconductor wafer mounted on the protective substrate removed off from the chuck means for grinding on a holding means, and thereafter, removing the protective substrate off from the front surface of the semiconductor wafer; and
the cutting step of holding the holding means mounting the semiconductor wafer on a chuck means for cutting and applying a cutting means to the exposed front surface of the semiconductor wafer to cut the semiconductor wafer along the streets.

2. The method of processing a semiconductor wafer according to claim 1, wherein the holding means is constituted by a mounting frame having a mounting opening at the center and a mounting tape affixed to the mounting frame in such a manner that it strides over the mounting opening, and, in the transfer step, the back surface of the semiconductor wafer mounted on the protective substrate removed off from the chuck means for grinding is affixed to the mounting tape in the mounting opening of the mounting frame in order to mount the semiconductor wafer on the holding means.

3. The method of processing a semiconductor wafer according to claim 1, wherein in the mounting step, a resin solution is coated onto the front surface of the semiconductor wafer, a solvent is evaporated before or after the front surface of the semiconductor wafer is caused to be opposed to one side of the protective substrate in order to form a resin film having adhesion, and the semiconductor wafer is mounted on the protective substrate via the resin film.

4. The method of processing a semiconductor wafer according to claim 3, wherein the resin solution is applied to the front surface of the semiconductor wafer by supplying resin solution droplets onto the front surface of the semiconductor wafer and rotating the semiconductor wafer at a revolution of 10 to 3,000 rpm.

5. The method of processing a semiconductor wafer according to claim 3, wherein the resin film has a thickness of 1 to 100 μm.

6. The method of processing a semiconductor wafer according to claim 3, wherein in the transfer step, prior to the removal of the protective substrate from the front surface of the semiconductor wafer, a solvent is supplied to the resin film through the pores of the protective substrate to dissolve the resin film.

7. The method of processing a semiconductor wafer according to claim 6, wherein the resin solution is water-soluble, and the solvent is water.

8. The method of processing a semiconductor wafer according to claim 1, wherein in the mounting step, the front surface of the semiconductor wafer is adhered to the one side of the protective substrate by an adhesive double-coated tape.

9. The method of processing a semiconductor wafer according to claim 1, wherein in the mounting step, the front surface of the semiconductor wafer and the one side of the protective substrate are contact bonded together via water.

10. The method of processing a semiconductor wafer according to claim 9, wherein prior to contact bonding the front surface of the semiconductor wafer to the one side of the protective substrate through water, a protective resin tape is affixed to the front surface of the semiconductor wafer.

11. The method of processing a semiconductor wafer according to claim 9, wherein in the transfer step, the protective substrate is heated to evaporate water existing between the front surface of the semiconductor wafer and the protective substrate.

12. The method of processing a semiconductor wafer according to claim 1, wherein in the transfer step, prior to the affixing of the back surface of the semiconductor wafer to the mounting means, a die attach film is affixed to the back surface of the semiconductor wafer.

13. The method of processing a semiconductor wafer according to claim 1, wherein the protective substrate has a frame area surrounding the central area, pores are not formed in the frame area, and the semiconductor wafer is mounted within the central area of the protective substrate.

14. The method of processing a semiconductor wafer according to claim 13, wherein the area ratio of the pores to the central area of the protective substrate is 1 to 50%, and the pores have a diameter of 0.1 to 1.0 mm.

15. The method of processing a semiconductor wafer according to claim 13, wherein the protective substrate is formed of a sheet metal having a thickness of 0.1 to 1.0 mm.
